(19) United States
(12) Patent Application Publication
(10) Pub. No.: US 2025/0277993 A1
(43) Pub. Date: Sep. 4, 2025

(54) METHOD FOR DRIVING ELECTRO-ABSORPTION MODULATOR OPERATING IN BURST MODE

(71) Applicant: PHOVEL Co., Ltd., Daejeon (KR)

(72) Inventor: Jeong Soo Kim, Sejong-si (KR)

(21) Appl. No.: 19/210,056

(22) Filed: May 16, 2025

Related U.S. Application Data
(63) Continuation of application No. PCT/KR2023/003638, filed on Mar. 20, 2023.

(30) Foreign Application Priority Data
Dec. 27, 2022 (KR) 10-2022-0186175
Mar. 17, 2023 (KR) 10-2023-0035078

(51) Int. Cl. G02F 1/01; H01S 5/024; H01S 5/026

(52) U.S. Cl. CPC G02F 1/0121; H01S 5/02453; H01S 5/0265

(57) ABSTRACT

The present disclosure relates to a method for driving an electro-absorption modulator operating in a burst mode. In the method for driving an electro-absorption modulator operating in a burst mode according to the present disclosure, the magnitude of DC voltage and AC voltage for driving the electro-absorption modulator is functionally reduced according to the elapse of time from the time at which laser light is injected into the electro-absorption modulator so that light absorption begins, and thus offset light absorption characteristics due to changes in temperature of the electro-absorption modulator area can be offset.

### CROSS-REFERENCE TO RELATED APPLICATIONS

This application is a Continuation of Application No. PCT/KR2023/003638, filed on Mar. 20, 2023, which in turn claims the benefit of Korean Patent Applications No. 10-2022-0186175, filed on Dec. 27, 2022, and No. 10-2023-0035078, filed on Mar. 17, 2023. The entire disclosures of all these applications are hereby incorporated by reference.

### TECHNICAL FIELD

The present disclosure relates to a method for driving a modulator, and more particularly, to a method for driving an electro-absorption modulator operating in a burst mode.

### BACKGROUND ART

A light-emitting element currently used in high-speed optical communications is used in the form of a modulator-integrated semiconductor laser. In the modulator-integrated semiconductor laser (electro-absorption modulator integrated DFB-LD: EML), the distributed feed back-laser diode (DFB-LD) operates continuously, and an optical modulator is installed in an optical output part of the DFB-LD to generate a modulation signal using the optical modulator.

The operating characteristics of this optical modulator are as illustrated in FIG. 1.

An absorption spectrum curve according to a wavelength when a reverse voltage is not applied to the modulator shifts to a long wavelength as the absorption spectrum curve decreases when the reverse voltage is applied to the modulator. In FIG. 1, the modulator has a low absorption rate of B1 when an electric field E=0 V/cm for a light source of wavelength B fed into the modulator, and then, when a voltage of 5.4E4 V/cm is applied to the modulator, the absorption spectrum of the modulator changes to have a high absorption rate of B2, and the intensity of light passing through the modulator changes due to the difference in the absorption rates of B1 and B2. An element in which the intensity of light passing through the modulator is determined by the magnitude of the reverse voltage applied to the modulator is called an electro-absorption modulator.

Depending on a band gap of the modulator itself and a wavelength of incoming light, even with the same modulator, the modulator operation may occur at wavelengths C in FIG. 1 and D in FIG. 1. Therefore, a well-controlled constant relationship is required between the band gap of the modulator itself and the incoming wavelength. FIG. 2 illustrates a case where the absorption spectrum of the modulator itself is measured at 300K temperature, and is a diagram illustrating the change in the absorption spectrum when a voltage is applied to the modulator materials change their maintained at 300K. However, all temperature when they absorb energy, which varies depending on the amount of energy absorbed and the heat dissipation of the materials. The semiconductor material used as the absorbing material in the modulator changes its band gap depending on the temperature, and the absorption spectrum shifts according to the electric field from the wavelength of this changed band gap. This is illustrated in FIG. 2.

In FIG. 3, a blue absorption spectrum curve is the absorption spectrum curve according to temperature when no voltage applied, and a yellow color is the absorption spectrum curve that shifts according to the voltage at each temperature. Therefore, in order to obtain the intensity of light passing through the modulator and the exact extinction ratio (the ratio of the signal intensities of the “1” signal and the “0” signal), the temperature of the modulator and the applied voltage must be precisely controlled. That is, in FIG. 2, the extinction ratio when a zero voltage (E=0 V/cm) and E=5.4E4 V/cm are applied to the input light wavelength of “B” at a temperature of 300 K will be different from the extinction ratio when zero voltage (E=0 V/cm) and E=5.4E4 V/cm are applied to the same input light wavelength at a temperature of 310 K of the modulator, and the average optical output will also change.

The optical signal generated by the modulator, i.e., “1” and “0” signals, is transmitted through the optical fiber, and an optical receiver extracts the “1” and “0” signals using the statistical power and signal extinction ratio of the “1” and “0” signals. Therefore, when the modulator is driven using the same voltage from a time at which the modulator operates, the temperature of the modulator changes over time, and accordingly, the average power and extinction ratio of the signal generated from the modulator change, which acts as an error in the receiver.

The conventional electro-absorption modulator operates in a continuous wave (CW) (continuous operation), so that after the initial time has passed, the temperature of the modulator stabilizes and no additional change in temperature occurs in the modulator region. On the other hand, in the modulator operating in burst mode as illustrated in FIG. 4, the operation changes between a time when light is not applied to the modulator and a time when light is applied to the modulator to form a modulation signal, so the temperature of the optical absorption region of the modulator continuously changes according to the burst operation, and accordingly, the signal transmission using the modulator operating in the burst mode becomes difficult.

### RELATED ART DOCUMENT

### Patent Document

(Patent Document 1) Korean Patent Publication No. 10-0362060 (published on Nov. 11, 2002)

### DISCLOSURE

### Technical Problem

The present disclosure has been proposed to solve the problems occurring in the conventional electro-absorption modulator operating in a burst mode, and an object of the present disclosure provides a method for driving an electro-absorption modulator which can solve the problem that, in an electro-absorption modulator operating in a burst mode, the intensity of a light source entering a modulator changes depending on an operation of the light source, and accordingly, the temperature of the modulator changes depending on the intensity of light absorbed by the modulator, and under modulator driving conditions that do not take into account the change in temperature of the modulator, the average intensity and extinction ratio of light passing through the modulator change over time, making it difficult to distinguish signals at an optical receiver.

### Technical Solution

According to an exemplary embodiment, provided is a method for driving an electro-absorption modulator operating in a burst mode, in which magnitudes of DC voltage and AC voltage for driving the electro-absorption modulator are functionally reduced according to an elapse of time from a time at which laser light is injected into the electro-absorption modulator so that light absorption begins.

A function for reducing the magnitudes of the DC voltage and AC voltage over time may be preset and recorded in a memory.

A laser diode as a light source may be manufactured integrally in an optical input part of the electro-absorption modulator and operate.

An optical amplifier may be manufactured integrally in an optical output part of the electro-absorption modulator and operate.

The electro-absorption modulator may be a ridge type modulator having a deep ridge structure.

The electro-absorption modulator may produce a “0” signal with a DC voltage +½ modulation voltage and a “1” signal with a DC voltage −½ modulation voltage, or apply a modulation voltage of a process equivalent thereto, and a decreasing function of the DC voltage and the modulation voltage after the electro-absorption modulator operates may decrease exponentially over time.

The electro-absorption modulator may produce a “0” signal with a DC voltage +½ modulation voltage and a “1” signal with a DC voltage −½ modulation voltage, or apply a modulation voltage of a process equivalent thereto, and a decreasing function of the DC voltage and the modulation voltage after the electro-absorption modulator operates may be a function having a characteristic of offsetting temperature increase of the electro-absorption modulator over time.

The laser diode may be a reverse mesa structure having a heater mounted on an upper portion thereof.

The electro-absorption modulator may be a reverse mesa structure having a heater mounted on an upper portion thereof.

The heater mounted on the upper portion of the electro-absorption modulator may be driven to offset a change in temperature due to light absorption of the modulator operating in a burst mode.

The heater mounted on the upper portion of the electro-absorption modulator may be mounted on an upper electrode of the modulator, separated by an insulating film.

The heater mounted on the upper portion of the electro-absorption modulator may be connected to an external electrode in a form of an air bridge.

### Advantageous Effects

According to the method for driving the electro-absorption modulator operating in a burst mode of the present disclosure, it is possible to suppress the change in temperature due to the light absorption of the modulator operating in the burst mode and the change in optical output and extinction ratio according to the change in temperature, thereby facilitating the signal discrimination at the optical receiver.

### BRIEF DESCRIPTION OF THE DRAWINGS

FIG. 1 is a graph illustrating a change in absorption spectrum according to a voltage applied to an electro-absorption modulator.

FIG. 2 is an operating principle according to a driving voltage of the modulator.

FIG. 3 illustrates an example illustrating that an extinction ratio of a modulation signal changes according to the change in temperature of the modulator when the modulator is driven with a constant driving voltage regardless of a temperature of the modulator.

FIG. 4 illustrates an example of a burst mode operation of the modulator.

FIG. 5 illustrates an example of optical output characteristics of the modulator that is modulated by changing a driving voltage of the modulator to offset a change in temperature of an absorption region of the modulator according to the present disclosure.

FIG. 6 illustrates an example of the change in temperature according to an optical absorption time of the modulator region operating in the burst mode according to the present disclosure.

FIG. 7 is another example of the change in temperature of the modulator region according to the optical absorption from a time at which the modulator operates according to the present disclosure.

FIG. 8 illustrates an example of a light source having a reverse mesa ridge structure in which a s mounted according to the present disclosure.

FIG. 9 illustrates an example of a modulator with a reverse mesh ridge structure having a deep ridge structure in which a heater is mounted according to the present disclosure.

FIG. 10 illustrates an example of a heater driving method in the modulator in which the heater is mounted according to the present disclosure.

FIG. 11 illustrates an example of a change in temperature of the modulator when the burst on starts in the modulator according to the present disclosure and light absorption occurs, and at the same time, the heater stops and heat generation by the heater disappears.

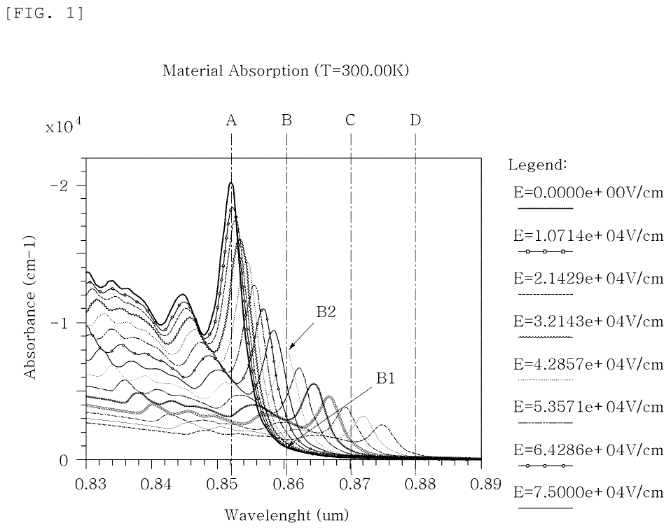

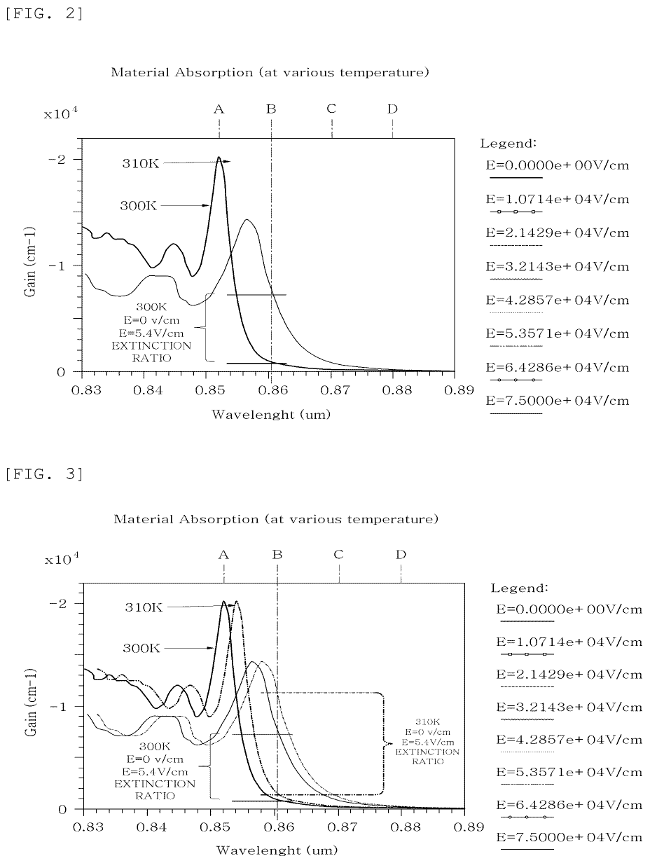

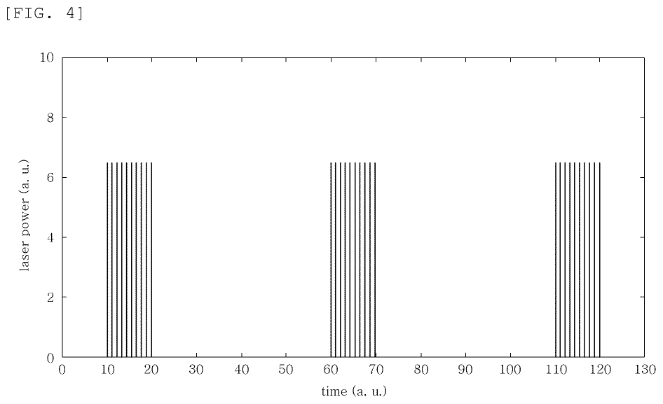

### BEST MODE

Hereinafter, unlimited preferred embodiments of the present disclosure will be described in detail with reference to the accompanying drawings.

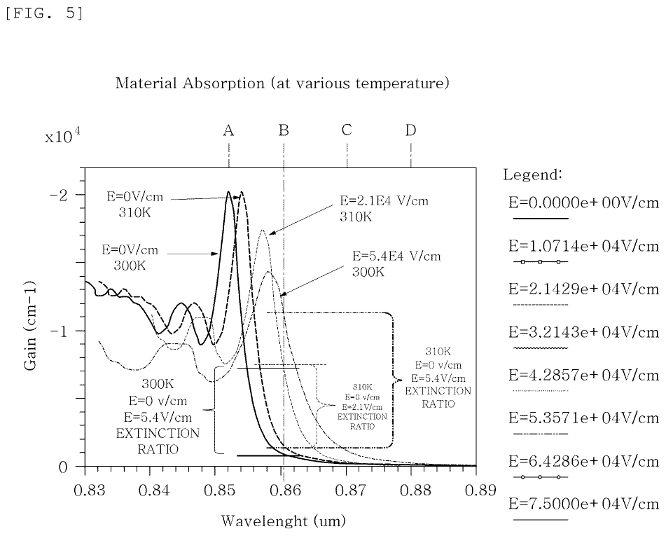

FIG. 5 illustrates an example of optical output characteristics of the modulator that is modulated by changing a driving voltage of the modulator to offset a change in temperature of an absorption region of the modulator according to the present disclosure.

FIG. 5 illustrates an extinction ratio under the driving voltage conditions of E=0 v/cm and E=5.4 V/cm, which are indicated in blue at a temperature of 300 K. A blue solid line is an absorption spectrum for 300 K and E=0 v/cm. In this case, an absorption of a “B” wavelength hardly occurs. A blue dotted line illustrates an absorption when an electric field of 5.4E4 V/cm is applied, from which an initial extinction ratio is determined. However, when this modulator starts absorbing light and the temperature of the modulator increases to 310 K, if the same electric field of 0 V/cm and 5.4E4 V/cm is applied, the extinction ratio becomes very large. Therefore, when the electric field is maintained the same, a change in temperature of a modulator region over time and a change in the extinction ratio accordingly are unavoidable.

In FIG. 5, when the temperature of the modulator is increased to 310K, if the electric field of the modulator changes to 0 V/cm and 2.1E4 V/cm, it can be seen that an extinction ratio similar to the extinction ratio that may be obtained at 300K, 0 V/cm, and 5.4E4 V/cm may be obtained.

As illustrated in FIG. 5, by changing a driving voltage by a method for minimizing a change in an extinction ratio due to the change in temperature according to the start of the burst mode and a change in an absorption curve according to the change in temperature of the modulator, the change in the extinction ratio may be minimized at the beginning and end of the burst.

Although the present disclosure has been described using the electric field, since an electric field direction length of the actually manufactured modulator is fixed, the change in the electric field may be implemented by the change in the voltage applied to the modulator. Typically, the voltage of the modulator is given as a sum of a DC voltage and an AC modulation voltage corresponding to “1” and “0” signals, so the change in the extinction ratio due to the change in the modulator temperature may be offset by the change in the DC voltage and the modulation voltage due to the change in the modulator temperature.

“1” signal voltage=DC voltage−½ AC modulation voltage

“0” signal voltage=DC voltage+½ AC modulation voltage

However, the modulation voltage does not necessarily have to be implemented in this way, and various methods are possible for applying voltages according to the “1” and “0” signals.

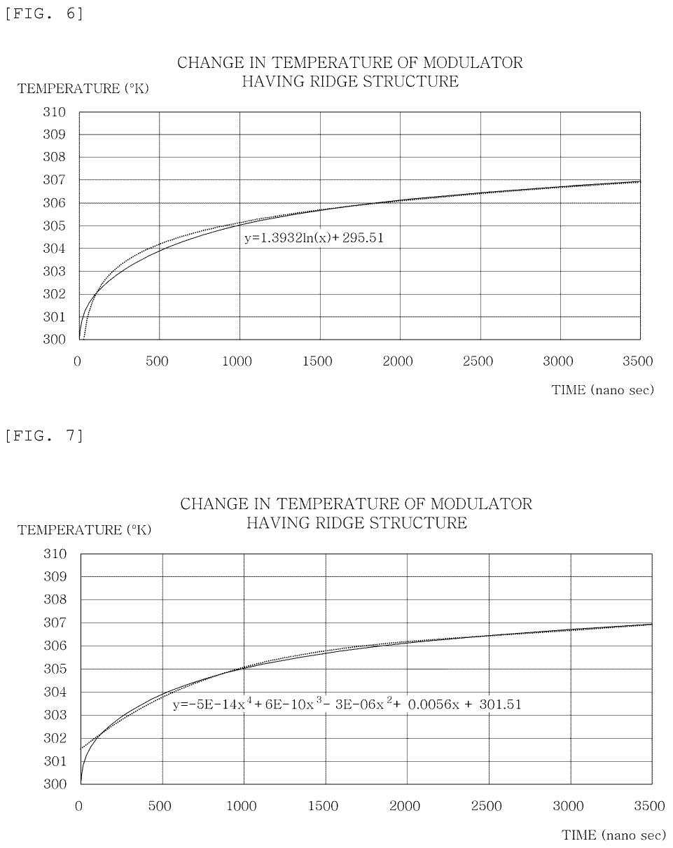

Basically, the change in temperature of the modulator leads to the change in the absorption spectrum. Accordingly, in order to obtain the change in the modulation voltage to offset the change in the modulation characteristics of the modulator, the change in temperature of the modulator according to the operating time of the modulator should first be measured. The change in temperature from the start of the operation of the modulator varies depending on the structure of the modulator and the intensity of light entering the modulator, and FIGS. 6 and 7 illustrate examples of the change in temperature from a time at which the modulator operates.

In FIGS. 6 and 7, the change in temperature of the modulator may be simulated as a change in temperature close to an exponential function and the fourth power of a high-order term. Since a wavelength shift of the modulator changes almost linearly with temperature, as illustrated in the examples in FIGS. 6 and 7, the change in temperature of the modulator is simulated first and the change in spectrum of the modulator is inferred accordingly, so the DC voltage and AC modulation voltage to offset the change in characteristics such as the extinction ratio of the modulator may be obtained as a function of time. There may be various changes in FIGS. 6 and 7, but the important point is that the changed DC voltage and AC modulation voltage to offset the change in temperature of the modulator over time and the change in characteristics of the modulator at each time are applied to the modulator.

A method can be used in which the changes in the DC voltage and AC modulation voltage of the modulator are substituted into a function from a time at which a burst signal starts and the modulation voltage of the actual modulator is adjusted from this function, or a method may be used in which a look-up table over time is stored in memory and the DC voltage and AC modulation voltage for driving the modulator are read from the memory to drive the modulator.

In order to manufacture a modulator that operates in a burst mode, a light source that operates in the burst mode is required, and the modulator and the light source are usually manufactured to be integrated. The light source is composed of a DFB-LD or a distributed Bragg reflector-laser diode (DBR-LD), and the wavelength of the light source itself changes depending on the burst mode operation of the light source. Therefore, the change in the wavelength of the light source itself should be suppressed, and it is preferable to embed an electric heater in one side or an upper portion of the DFB-LD. In order to facilitate the embedding of this heater, it is appropriate that the light source structure of the DFB-LD is a ridge structure having a reverse mesa structure.

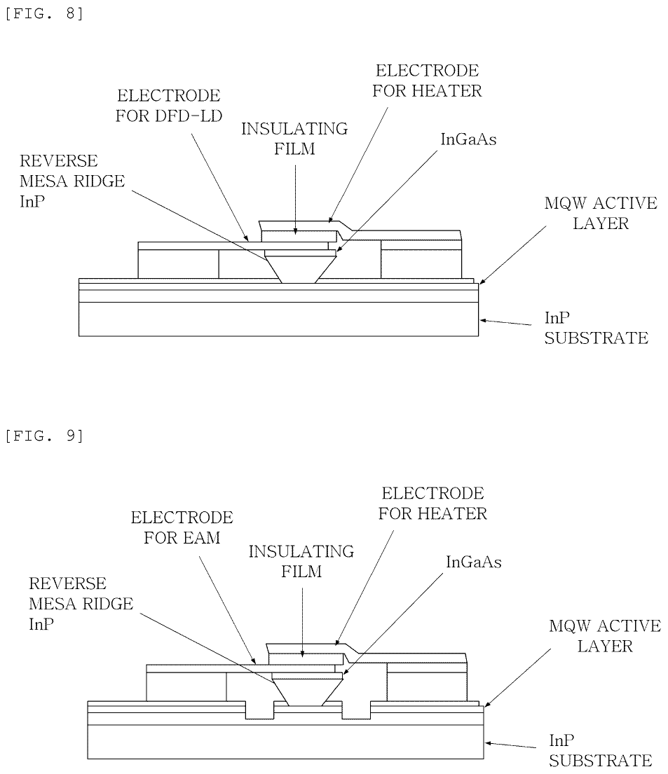

FIG. 8 illustrates an example of a light source having a reverse mesa ridge structure equipped with a heater according to an embodiment of the present disclosure. A current for operating the light is injected into an electrode (p-type source electrode) for the DFB-LD of FIG. 8, and the heater is arranged in the upper portion of the electrode for the DFB-LD and is driven complementarily with the current for operating the light source to offset the change in temperature in the laser diode region due to the burst mode operation of the laser diode. That is, the heater is mounted in the upper portion of the DFB-LD light source, and the structure of the DBB-LD light source has a reverse mesa ridge structure that makes it easy to mount the heater in the upper portion. The reverse mesa ridge means a structure in which an upper portion of a clad layer composed of p-InP/P—InGaAs layers is wider than a lower portion. In FIG. 8, since the electrode for operating the light source is arranged in the upper portion of the mesa, it is preferable that the heater is manufactured by being separated by an insulating film and overlapping on the upper electrode for driving the light source.

The characteristics to be improved in the present disclosure are that the period in which the modulator performs light absorption and modulation transmission appears in the form of a burst, and there is no light absorption in the modulator during a period other than a burst on time, so the modulator is cooled, and the light absorption begins during the burst on time and the temperature of the modulator rises. As a result, the light absorption characteristics also change over time. Therefore, the method described above uses a change in driving voltage of the modulator to offset the change in temperature of the modulator to maintain the characteristics of the light absorption of the modulator constant, while the method for mounting the heater on the modulator may be used as the method for maintaining the characteristics of the light absorption of the optical modulator constant after the burst on.

FIG. 9 illustrates an example of a modulator of a reverse mesh ridge structure having a deep ridge structure in which the heater is mounted according to the present disclosure.

In FIG. 9, two grooves are formed on both sides of the modulator having the reverse mesa ridge structure on the substrate, these grooves form a deep ridge structure, and the deep ridge structure concentrates the electric field of the modulator on the active region, thereby improving the characteristics of the modulator. FIG. 9 illustrates a method for mounting a heater in a modulator region to keep the heater off while the role modulator performs the of light absorption/light modulation/light transmission, and operate the heater to prevent cooling when the modulator does not perform the role of light absorption/light modulation/light transmission, thereby always maintaining the modulator at a constant temperature regardless of whether the modulator is in operation and preventing the change in temperature due to the light absorption of the modulator and the change in optical modulation characteristics due to the change in temperature.

In FIG. 9, the heater is mounted on the upper portion of the modulator, and it is preferable that the structure of the modulator has a structure of the reverse mesa ridge so that the heater may be easily mounted on the upper portion. The reverse mesa ridge refers to a structure in which an upper portion of a clad layer composed of the p-InP/P—InGaAs layers is wider than a lower portion. A lower width of the ridge has 1 to 2 μm so that light has a single transverse mode, while an upper width of the ridge may have a width of at least 0.5 μm or more. It is more preferable that a cross-section of the ridge is a (111) plane. In this case, the upper width of the ridge may be 2 to 3 μm wider than the lower width of the ridge, making it easy to additionally mount the heater.

In FIG. 9, it is preferable for the high-speed modulator to minimize capacitance, and accordingly, it is preferable for the heater electrode to be connected to the external electrode in the form of the air bridge to minimize parasitic capacitance. This electrode in the form of the air bridge is manufactured in the form in which the part where the electrode metal is connected to the pad is floating in the air, which minimizes the parasitic capacitance generated at the connection part of the heater pad, facilitating the high-speed operation of the device. In addition, since the electrode for operating the modulator is arranged in the upper portion of the mesa, it is preferable that the heater is manufactured by being separated by the insulating film and overlapping on the upper electrode for driving the modulator. In FIG. 9, the insulating film, etc., for protecting InP is not illustrated for the sake of a brief description, but a surface protection layer, such as an insulating film of a general modulator structure, may be added.

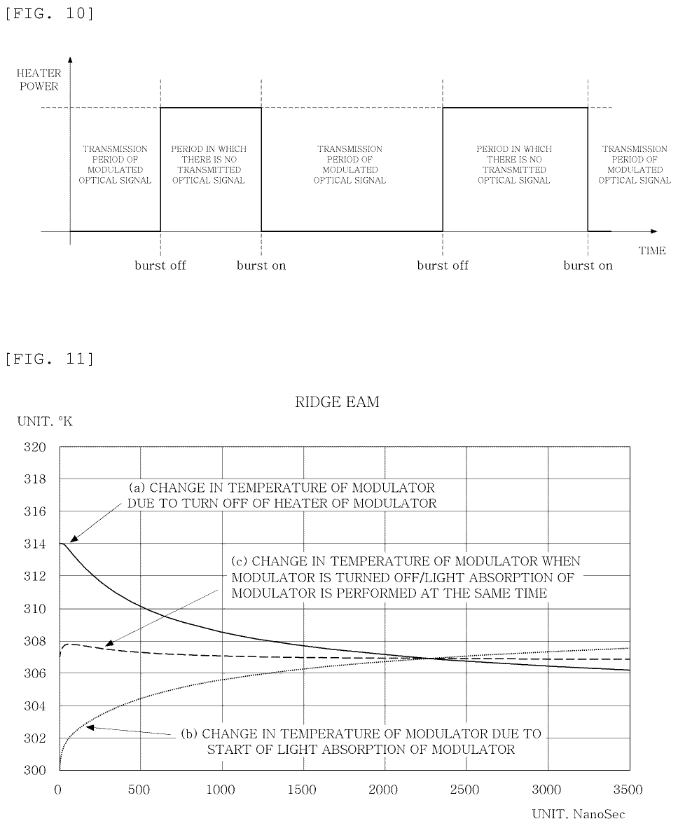

FIG. 10 illustrates a method of driving a heater in a modulator equipped with the heater. The heater is turned off during a burst on period in which the light absorption/light modulation/light transmission occurs in the modulator, and the heater is turned on during a burst-off period in which no light is supplied to the modulator, thereby replacing the light absorption power occurring in the modulator and maintaining the temperature of the modulator constant regardless of the burst on/off.

The change in temperature of the modulator when the burst on starts in the modulator and the light absorption occurs, and at the same time, the heater is stopped and the heat generation by the heater disappears is illustrated in FIG. 11. The temperature by the heater, which is curve a in 11, FIG. 11, illustrates the change in temperature of the modulator over time when the heater stops generating heat when there is no light absorption, and the temperature of light absorption, which is curve b of FIG. 11, illustrates the change in temperature of the modulator when the light absorption starts in the modulator in the state in which the heater is not operating. Therefore, when these two effects occur simultaneously, the average effect of the two effects of the (a) and (b) is represented by curve (c) of FIG. 11, and as illustrated in curve (c) of FIG. 11, the temperature of the modulator is maintained constant regardless of the burst on/off, so the characteristics of the modulator may be stable.

In this way, in the present disclosure, the DC voltage and the modulation voltage driving the modulator change as a function over time, and the modulator is driven to offset the change in temperature of the modulator according to the modulator driving time, so the average intensity and extinction ratio of the output optical signal of the modulator may be maintained constant.

Meanwhile, in FIG. 9 described above, the power modulation of the heater does not need to alternate between a predetermined power and power of 0, and the purpose of the present disclosure may be achieved if the heater modulation power offsets the heat amount change due to the light absorption of the modulator.

In addition, although the light source such as the DFB-LD in FIGS. 8 and 9 has been described as having the reverse mesa ridge structure and the modulator also has the reverse mesa ridge structure, a combination of the light source such as the DBR-LD having the mesa structure and the reverse mesa modulator structure equipped with the heater is also possible.

As described above, the present disclosure is not limited to the exemplary embodiment described above, but may be variously modified and altered without departing from the spirit and scope of the present disclosure and equivalents to the following claims by those skilled in the art to which the present disclosure pertains.

1. A method for driving an electro-absorption modulator operating in a burst mode, wherein magnitudes of DC voltage and AC voltage for driving the electro-absorption modulator are functionally reduced according to an elapse of time from a time at which laser light is injected into the electro-absorption modulator so that light absorption begins.

2. The method of claim 1, wherein a function for reducing the magnitudes of the DC voltage and AC voltage over time is preset and recorded in a memory.

3. The method of claim 1, wherein a laser diode as a light source is manufactured integrally in an optical input part of the electro-absorption modulator and operates.

4. The method of claim 1, wherein an optical amplifier is manufactured integrally in an optical output part of the electro-absorption modulator and operates.

5. The method of claim 1, wherein the electro-absorption modulator is a ridge type modulator having a deep ridge structure.

6. The method of claim 1, wherein the electro-absorption modulator produces a “0” signal of the electro-absorption modulator with a DC voltage +½ modulation voltage and a “1” signal of the electro-absorption modulator with a DC voltage −½ modulation voltage, or applies a modulation voltage of a process equivalent thereto, and
a decreasing function of the DC voltage and the modulation voltage after the electro-absorption modulator operates decreases exponentially over time.

7. The method of claim 1, wherein the electro-absorption modulator produces a “0” signal of the electro-absorption modulator with a DC voltage +½ modulation voltage and a “1” signal of the electro-absorption modulator with a DC voltage −½ modulation voltage, or applies a modulation voltage of a process equivalent thereto, and
a decreasing function of the DC voltage and the modulation voltage after the electro-absorption modulator operates is a function having a characteristic of offsetting a temperature increase of the electro-absorption modulator over time.

8. The method of claim 3, wherein the laser diode is a reverse mesa structure having a heater mounted on an upper portion thereof.

9. The method of claim 1, wherein the electro-absorption modulator is a reverse mesa structure having a heater mounted on an upper portion thereof.

10. The method of claim 9, wherein the heater mounted on the upper portion of the electro-absorption modulator is driven to offset a change in temperature due to light absorption of the modulator operating in a burst mode.

11. The method of claim 9, wherein the heater mounted on the upper portion of the electro-absorption modulator is mounted on an upper electrode of the modulator, separated by an insulating film.

12. The method of claim 9, wherein the heater mounted on the upper portion of the electro-absorption modulator is connected to an external electrode in a form of an air bridge.
